(19) United States
(12) Patent Application Publication
(10) Pub. No.: US 2025/0330273 A1
(43) Pub. Date: Oct. 23, 2025

(54) METHODS, SYSTEM, AND APPARATUS FOR RATE COMPATIBLE WOVEN CODES

(71) Applicant: Huawei Technologies Co., Ltd., Shenzhen (CN)

(72) Inventors: Huazi Zhang, Shenzhen (CN); Jianglei Ma, Ottawa (CA); Wen Tong, Ottawa (CA)

(21) Appl. No.: 19/258,457

(22) Filed: Jul. 2, 2025

Related U.S. Application Data
(63) Continuation of application No. PCT/CN2023/070019, filed on Jan. 3, 2023.

(51) Int. Cl. H04L 1/00

(52) U.S. Cl. CPC H04L 1/0071; H04L 1/0067

(57) ABSTRACT

Information bits are encoded by a woven code. The woven code includes a first code, block interleaving, and a second code. The block interleaving involves row-wise writing, in a number of rows, of first code encoded bits that have been encoded by the first code, respective permutations according to which the first code encoded bits in the rows are permuted, and column-wise reading of the permuted first code encoded bits for further encoding by the second code. For rate compatibility, rate matching such as puncturing may be applied. In some embodiments, the respective permutations are based on respective prime numbers.

### CROSS-REFERENCE TO RELATED APPLICATIONS

This application is a continuation of International Application No. PCT/CN2023/070019, entitled “METHODS, SYSTEM, AND APPARATUS FOR RATE COMPATIBLE WOVEN CODES” and filed on Jan. 3, 2023, the disclosure of which is hereby incorporated by reference in its entirety.

### TECHNICAL FIELD

The present application relates to wireless communications, and in particular to rate matching and channel coding for wireless communications.

### BACKGROUND

Certain types of communications, such as ultra-reliable low latency communications (URLLC) for example, may require powerful channel coding schemes. In particular for URLLC, channel codes that exhibit no or low error floor may be preferred because URLLC has a target block error rate (BLER) below 10⁻⁴. Channel codes used for URLLC should perform well at short codeword length and at low code rates, but these channel codes should also support flexible code lengths and code rates.

Turbo codes, as used in long term evolution (LTE) systems for example, perform well at low code rate, especially around rate 1/3. However, these codes have an error floor above BLER=104 and therefore may not be suitable for at least certain applications such as URLLC.

Low density parity check (LDPC) codes perform well at high code rate, but not at low code rate. Moreover, short LDPC codes tend to have an error floor above BLER=10⁻⁴.

Woven codes are a new family of serially concatenated codes that exhibit excellent performance and low error floor at low code rates. However, such codes have not been fully investigated for wireless applications.

Providing effective channel coding for applications such as URLLC, which have relatively demanding requirements, remains a challenge.

### SUMMARY

The present disclosure encompasses embodiments that may be useful in addressing various technical shortcomings of current coding methods, including rate compatibility and interleaving for example. Rate compatibility is provided in some embodiments by applying puncturing and/or other types of rate matching. Embodiments may also or instead involve prime number-based row-wise permutations,

According to an aspect of the present disclosure, a method involves transmitting, by a first communication device to a second communication device in a wireless communication network, encoded bits encoded by a woven code. The woven code includes a first code, block interleaving, and a second code. The block interleaving involves row-wise writing of first code encoded bits encoded by the first code in a plurality of rows, respective permutations according to which the first code encoded bits in the plurality of rows are permuted, and column-wise reading of the permuted first code encoded bits for further encoding by the second code. The respective permutations are based on respective prime numbers.

Another method involves encoding information bits by a woven code to generate encoded bits, and outputting the encoded bits. The encoding includes encoding the information bits by a first code, block interleaving first code encoded bits encoded by the first code, and further encoding block interleaved first code encoded bits by a second code. The block interleaving involves row-wise writing of the first code encoded bits in a plurality of rows, respective permutations that are based on respective prime numbers and according to which the first code encoded bits in the plurality of rows are permuted, and column-wise reading of the permuted first code encoded bits for the further encoding by the second code.

A method according to another embodiment involves receiving, from a first communication device by a second communication device in a wireless communication network, encoded bits encoded by a woven code. The woven code, as above, involves includes a first code, block interleaving, and a second code, and the block interleaving involves row-wise writing of first code encoded bits encoded by the first code in a plurality of rows, respective permutations based on respective prime numbers and according to which the first code encoded bits in the plurality of rows are permuted, and column-wise reading of the permuted first code encoded bits for further encoding by the second code.

Yet another method disclosed herein involves decoding information bits from encoded bits encoded by a woven code that incudes a first code, block interleaving, and a second code, and outputting the information bits. The block interleaving involves row-wise writing of first code encoded bits encoded by the first code in a plurality of rows, permuting the first code encoded bits in the plurality of rows according to respective permutations for each row of the plurality of rows, and column-wise reading of the permuted first code encoded bits for further encoding by the second code to generate the encoded bits. The respective permutations are based on respective prime numbers.

In apparatus embodiments, an apparatus may include a processor and a non-transitory computer readable storage medium that is coupled to the processor. The non-transitory computer readable storage medium stores programming for execution by the processor.

A storage medium need not necessarily or only be implemented in or in conjunction with such an apparatus. A computer program product, for example, may be or include a non-transitory computer readable medium storing programming for execution by a processor.

Programming stored by a computer readable storage medium may include instructions to, or to cause a processor to, perform, implement, support, or enable any of the methods disclosed herein.

For example, the programming may include instructions to or to cause a processor totransmit, by a first communication device to a second communication device in a wireless communication network, encoded bits encoded by a woven code. As in a method embodiment above, the woven code includes a first code, block interleaving, and a second code, the block interleaving involves row-wise writing of first code encoded bits encoded by the first code in a plurality of rows, respective permutations according to which the first code encoded bits in the plurality of rows are permuted, and column-wise reading of the permuted first code encoded bits for further encoding by the second code, and the respective permutations are based on respective prime numbers.

Programming may include instructions to or to cause a processor to: encode information bits by a woven code to generate encoded bits by encoding the information bits by a first code, block interleaving first code encoded bits encoded by the first code, and further encoding block interleaved first code encoded bits by a second code; and output the encoded bits. The block interleaving involves row-wise writing of the first code encoded bits in a plurality of rows, permuting the first code encoded bits in the plurality of rows according to respective permutations for each row of the plurality of rows, and column-wise reading of the permuted first code encoded bits for the further encoding by the second code, with the respective permutations being based on respective prime numbers.

In another embodiment, programming includes instructions to or to cause a processor to receive, from a first communication device by a second communication device in a wireless communication network, encoded bits encoded by a woven code, the woven code comprising a first code, block interleaving, and a second code. As in other embodiments, the block interleaving involves row-wise writing of first code encoded bits encoded by the first code in a plurality of rows, respective permutations that are based on respective prime numbers and according to which the first code encoded bits in the plurality of rows are permuted, and column-wise reading of the permuted first code encoded bits for further encoding by the second code.

A further embodiment relates to programming that includes instructions to or to cause a processor to decode information bits from encoded bits encoded by a woven code and output the information bits. The woven code includes a first code, block interleaving, and a second code, the block interleaving involves row-wise writing of first code encoded bits encoded by the first code in a plurality of rows, permuting the first code encoded bits in the plurality of rows according to respective permutations for each row of the plurality of rows, and column-wise reading of the permuted first code encoded bits for further encoding by the second code to generate the encoded bits, and the respective permutations are based on respective prime numbers.

A system is also disclosed, and may include a first communication device configured to transmit encoded bits and a second communication device configured to receive the encoded bits from the first communication device and to decode the encoded bits obtain information bits from the encoded bits. The encoded bits are encoded by a woven code that includes a first code, block interleaving, and a second code, the block interleaving involves row-wise writing of first code encoded bits encoded by the first code in a plurality of rows, respective permutations according to which the first code encoded bits in the plurality of rows are permuted, and column-wise reading of the permuted first code encoded bits for further encoding by the second code, and the respective permutations are based on respective prime numbers.

The present disclosure encompasses these and other aspects or embodiments.

### BRIEF DESCRIPTION OF THE DRAWINGS

For a more complete understanding of the present embodiments, and the advantages thereof, reference is now made, by way of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 is a block diagram illustrating an example encoder according to an embodiment.

FIG. 6 is a block diagram illustrating an example decoder according to an embodiment.

FIG. 7 is a block diagram illustrating an example encoder according to another embodiment.

FIG. 8 is a block diagram illustrating an example decoder according to another embodiment.

FIG. 9 includes block diagrams illustrating an interleaving example.

FIG. 10 is a block diagram illustrating an example of puncturing according to an embodiment.

FIG. 11 is a flow diagram illustrating example methods according to embodiments.

FIG. 12 is a plot of simulation results.

### DETAILED DESCRIPTION OF ILLUSTRATIVE EMBODIMENTS

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

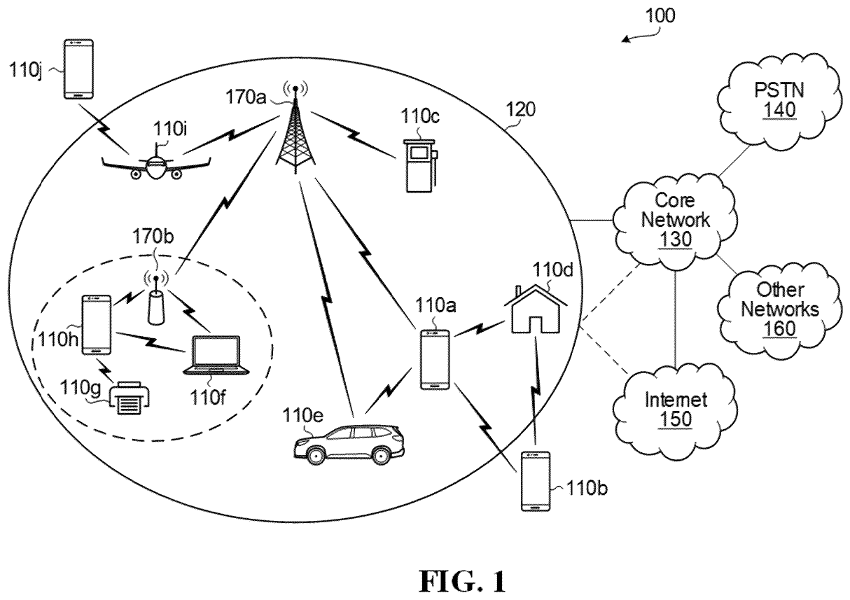

Referring to FIG. 1, as an illustrative example without limitation, a simplified schematic illustration of a communication system is provided. The communication system 100 comprises a radio access network 120. The radio access network 120 may be a next generation (e.g., sixth generation, “6G,” or later) radio access network, or a legacy (e.g., 5G, 4G, 3G or 2G) radio access network. One or more communication electric device (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

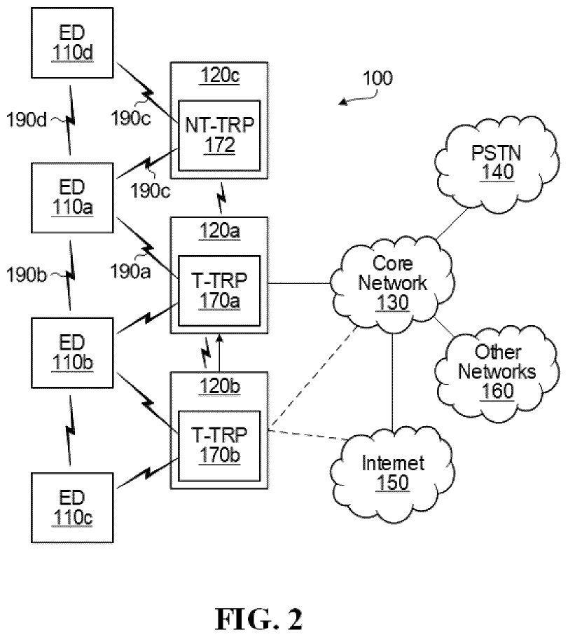

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150 and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, the ED 110a may communicate an uplink and/or downlink transmission over a terrestrial air interface 190a with T-TRP 170a. In some examples, the EDs 110a, 110b, 110c and 110d may also communicate directly with one another via one or more sidelink air interfaces 190b. In some examples, the ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 175 for multicast transmission.

The RANs 120a and 120b are in communication with the core network 130 to provide the EDs 110a, 110b, 110c with various services such as voice, data and other services. The RANs 120a and 120b and/or the core network 130 may be in direct or indirect communication with one or more other RANs (not shown), which may or may not be directly served by core network 130 and may, or may not, employ the same radio access technology as RAN 120a, RAN 120b or both. The core network 130 may also serve as a gateway access between (i) the RANs 120a and 120b or the EDs 110a, 110b, 110c or both, and (ii) other networks (such as the PSTN 140, the Internet 150, and the other networks 160). In addition, some or all of the EDs 110a, 110b, 110c may include functionality for communicating with different wireless networks over different wireless links using different wireless technologies and/or protocols. Instead of wireless communication (or in addition thereto), the EDs 110a, 110b, 110c may communicate via wired communication channels to a service provider or switch (not shown) and to the Internet 150. The PSTN 140 may include circuit switched telephone networks for providing plain old telephone service (POTS). The Internet 150 may include a network of computers and subnets (intranets) or both and incorporate protocols, such as Internet Protocol (IP), Transmission Control Protocol (TCP), User Datagram Protocol (UDP). The EDs 110a, 110b, 110c may be multimode devices capable of operation according to multiple radio access technologies and may incorporate multiple transceivers necessary to support such.

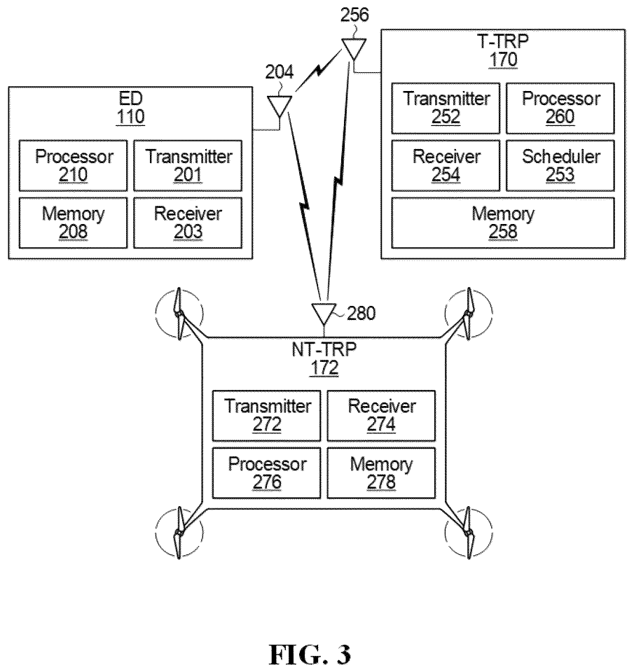

FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), Internet of things (IoT), virtual reality (VR), augmented reality (AR), industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, an industrial device, or apparatus (e.g., communication module, modem, or chip) in the forgoing devices, among other possibilities. Future generation EDs 110 may be referred to using other terms. The base stations 170a and 170b each T-TRPs and will, hereafter, be referred to as T-TRP 170. Also shown in FIG. 3, a NT-TRP will hereafter be referred to as NT-TRP 172. Each ED 110 connected to the T-TRP 170 and/or the NT-TRP 172 can be dynamically or semi-statically turned-on (i.e., established, activated or enabled), turned-off (i.e., released, deactivated or disabled) and/or configured in response to one of more of: connection availability; and connection necessity.

The ED 110 includes a transmitter 201 and a receiver 203 coupled to one or more antennas 204. Only one antenna 204 is illustrated. One, some, or all of the antennas 204 may, alternatively, be panels. The transmitter 201 and the receiver 203 may be integrated, e.g., as a transceiver. The transceiver is configured to modulate data or other content for transmission by the at least one antenna 204 or by a network interface controller (NIC). The transceiver may also be configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to, or receiving information from, a user, such as through operation as a speaker, a microphone, a keypad, a keyboard, a display or a touch screen, including network interface communications.

The ED 110 includes the processor 210 for performing operations including those operations related to preparing a transmission for uplink transmission to the NT-TRP 172 and/or the T-TRP 170, those operations related to processing downlink transmissions received from the NT-TRP 172 and/or the T-TRP 170, and those operations related to processing sidelink transmission to and from another ED 110. Processing operations related to preparing a transmission for uplink transmission may include operations such as encoding, modulating, transmit beamforming and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g., beam angle information (BAI), received from the T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201 and the processing components of the receiver 203 may each be implemented by the same or different one or more processors that are configured to execute instructions stored in a memory (e.g., the in memory 208). Alternatively, some or all of the processor 210, the processing components of the transmitter 201 and the processing components of the receiver 203 may each be implemented using dedicated circuitry, such as a programmed field-programmable gate array (FPGA), a graphical processing unit (GPU), or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a remote radio head, a terrestrial node, a terrestrial network device, a terrestrial base station, a base band unit (BBU), a remote radio unit (RRU), an active antenna unit (AAU), a remote radio head (RRH), a central unit (CU), a distribute unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g., a communication module, a modem or a chip) in the forgoing devices.

In some embodiments, the parts of the T-TRP 170 may be distributed. For example, some of the modules of the T-TRP 170 may be located remote from the equipment that houses antennas 256 for the T-TRP 170, and may be coupled to the equipment that houses antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses antennas 256 of the T-TRP 170. The modules may also be coupled to other T-TRPs. In some embodiments, the T-TRP 170 may actually be a plurality of T-TRPs that are operating together to serve the ED 110, e.g., through the use of coordinated multipoint transmissions.

The T-TRP 170 includes at least one transmitter 252 and at least one receiver 254 coupled to one or more antennas 256. Only one antenna 256 is illustrated. One, some, or all of the antennas 256 may, alternatively, be panels. The transmitter 252 and the receiver 254 may be integrated as a transceiver. The T-TRP 170 further includes a processor 260 for performing operations including those related to: preparing a transmission for downlink transmission to the ED 110; processing an uplink transmission received from the ED 110; preparing a transmission for backhaul transmission to the NT-TRP 172; and processing a transmission received over backhaul from the NT-TRP 172. Processing operations related to preparing a transmission for downlink or backhaul transmission may include operations such as encoding, modulating, precoding (e.g., multiple input multiple output (MIMO) precoding), transmit beamforming and generating symbols for transmission. Processing operations related to processing received transmissions in the uplink or over backhaul may include operations such as receive beamforming, demodulating received symbols and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates an indication of beam direction, e.g., BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling,” as used herein, may alternatively be called control signaling. Dynamic signaling may be transmitted in a control channel, e.g., a physical downlink control channel (PDCCH) and static, or semi-static, higher layer signaling may be included in a packet transmitted in a data channel, e.g., in a physical downlink shared channel (PDSCH).

The scheduler 253 may be coupled to the processor 260. The scheduler 253 may be included within, or operated separately from, the T-TRP 170. The scheduler 253 may schedule uplink, downlink and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252 and the processing components of the receiver 254 may each be implemented by the same, or different one of, one or more processors that are configured to execute instructions stored in a memory, e.g., in the memory 258. Alternatively, some or all of the processor 260, the scheduler 253, the processing components of the transmitter 252 and the processing components of the receiver 254 may be implemented using dedicated circuitry, such as a FPGA, a GPU or an ASIC.

Notably, the NT-TRP 172 is illustrated as a drone only as an example, the NT-TRP 172 may be implemented in any suitable non-terrestrial form. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110; processing an uplink transmission received from the ED 110; preparing a transmission for backhaul transmission to T-TRP 170; and processing a transmission received over backhaul from the T-TRP 170. Processing operations related to preparing a transmission for downlink or backhaul transmission may include operations such as encoding, modulating, precoding (e.g., MIMO precoding), transmit beamforming and generating symbols for transmission. Processing operations related to processing received transmissions in the uplink or over backhaul may include operations such as receive beamforming, demodulating received signals and decoding received symbols. In some embodiments, the processor 276 implements the transmit beamforming and/or receive beamforming based on beam direction information (e.g., BAI) received from the T-TRP 170. In some embodiments, the processor 276 may generate signaling, e.g., to configure one or more parameters of the ED 110. In some embodiments, the NT-TRP 172 implements physical layer processing but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272 and the processing components of the receiver 274 may each be implemented by the same or different one or more processors that are configured to execute instructions stored in a memory, e.g., in the memory 278. Alternatively, some or all of the processor 276, the processing components of the transmitter 272 and the processing components of the receiver 274 may be implemented using dedicated circuitry, such as a programmed FPGA, a GPU or an ASIC. In some embodiments, the NT-TRP 172 may actually be a plurality of NT-TRPs that are operating together to serve the ED 110, e.g., through coordinated multipoint transmissions.

The T-TRP 170, the NT-TRP 172, and/or the ED 110 may include other components, but these have been omitted for the sake of clarity.

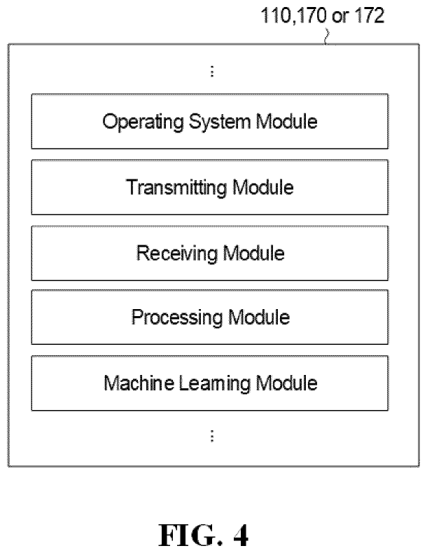

One or more steps of the embodiment methods provided herein may be performed by corresponding units or modules, according to FIG. 4. FIG. 4 illustrates units or modules in a device, such as in the ED 110, in the T-TRP 170 or in the NT-TRP 172. For example, a signal may be transmitted by a transmitting unit or by a transmitting module. A signal may be received by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU or an ASIC. It will be appreciated that where the modules are implemented using software for execution by a processor, for example, the modules may be retrieved by a processor, in whole or part as needed, individually or together for processing, in single or multiple instances, and that the modules themselves may include instructions for further deployment and instantiation.

Additional details regarding the EDs 110, the T-TRP 170 and the NT-TRP 172 are known to those of skill in the art. As such, these details are omitted here.

Having considered communications more generally above, attention will now turn to particular example embodiments.

Rate matching refers to a procedure to modify a mother code, by techniques such as puncturing, shortening, or repetition, for example, such that the modified code can achieve arbitrary lengths and code rates. Typically, a mother code supports very limited code lengths and code rates. However, in wireless communications, channel codes should be very flexible, providing a rich choice of code lengths and code rates, to adapt to varying channel conditions. Therefore, rate matching is an important procedure to make codes rate compatible, or in other words, compatible with or adaptable to different code lengths and code rates.

Woven convolutional codes are serially concatenated codes with both convolutional outer codes and inner codes. Outer code bits are interleaved before being encoded by inner codes. A block interleaver writes outer code bits to memory in row-wise order and reads the outer code bits in column-wise order for subsequent encoding by inner codes. The encoded bits after the encoding by the inner codes are similarly written in column-wise order.

There can be one or multiple outer convolutional codes, and one or multiple inner convolutional codes. A parallel set of outer codes may be referred to as an outer warp, and a parallel set of inner codes may be referred to as an inner warp; the structure is referred to as a warp because it resembles the warp in a weaving loom. A code with multiple outer codes but a single inner code may be referred to as a woven convolutional code with an outer warp. A code with multiple inner codes but a single outer code may be referred to as a woven convolutional code with an inner warp. A code with both multiple outer codes and multiple inner codes may be referred to as a woven convolutional code with a twill.

Woven convolutional codes are typically very long, and need to be decoded using sliding-window algorithms. A sliding window design is suitable for communication services with continuous traffic and large code length. However, a long code with sliding window decoding leads to relatively long latency, and this design is not suitable for latency-sensitive applications such as URLLC services.

A block woven code may provide shorter codes, which are better suited for wireless communications. In block woven codes, block interleaving is performed after collecting all outer code bits. The same “row-in, column-out” type of interleaving that is referenced above is applied to block woven codes, but the number of rows does not need to be the same as the number of outer codes, and the number of columns can be different from the number of inner codes. This results in a more flexible structure.

Although previous research on woven codes encompasses a general framework, including the theory and encoding and decoding methods, such a general framework does not specify or encompass more practical aspects of rate matching to provide rate compatibility, or block interleaving such as determining the width and height of a block interleaver, for example.

One technical problem that is considered herein is how to implement rate compatible block woven codes in a practical communication system. Rate matching techniques that may be used for providing rate compatibility include puncturing, shortening, and repetition. Woven codes with convolutional codes as component codes, for example, have only one mother code rate. To obtain variable-rate codes, in some embodiments repetition, puncturing, or both, may be used. Reducing the code rate can be accomplished by repetition, which may be shown to be simple and effective based on low-rate mother codes. Increasing the code rate can be accomplished by puncturing or otherwise reducing the number of coded bits; however, these techniques for increasing the code rate can result in performance degradation if not carefully designed.

The present disclosure also considers a technical problem of how to design a description-friendly and hardware-friendly block interleaver for woven codes. One conventional block interleaver applies a random permutation to each row of the block interleaver. However, pure random permutation is difficult to describe, in a communication standard or specification for example, which can result in a tangible loss of interoperability in practical communication systems. Moreover, a pure random permutation is also difficult to implement in hardware. Simpler and lower-complexity permutations may be more description-friendly in terms of defining or specifying how block interleaving is to be performed, and/or more hardware-friendly in terms of block interleaver implementation. Moreover, interleaving parameters such as width and height of a block interleaver may have significant impact on performance, and therefore it is important to appropriately determine such parameters.

Aspects of the present disclosure include adding subblock interleaving and puncturing to each component convolutional encoder, a prime number-based row-wise permutation for block interleaving, and a recurrent puncturing technique. Each of these aspects is described generally herein, and detailed examples are also provided.

Regarding the first aspect above, in some embodiments a more flexible component code module includes a convolutional encoder and two subblock interleavers, and a puncturing pattern is used to tailor the component convolutional code. For example, systematic bits may be routed directly through a subblock interleaver, and parity bits generated by the convolutional encoder may be routed through another subblock interleaver. The two interleaved streams may then be concatenated and punctured according to a pre-defined puncturing pattern.

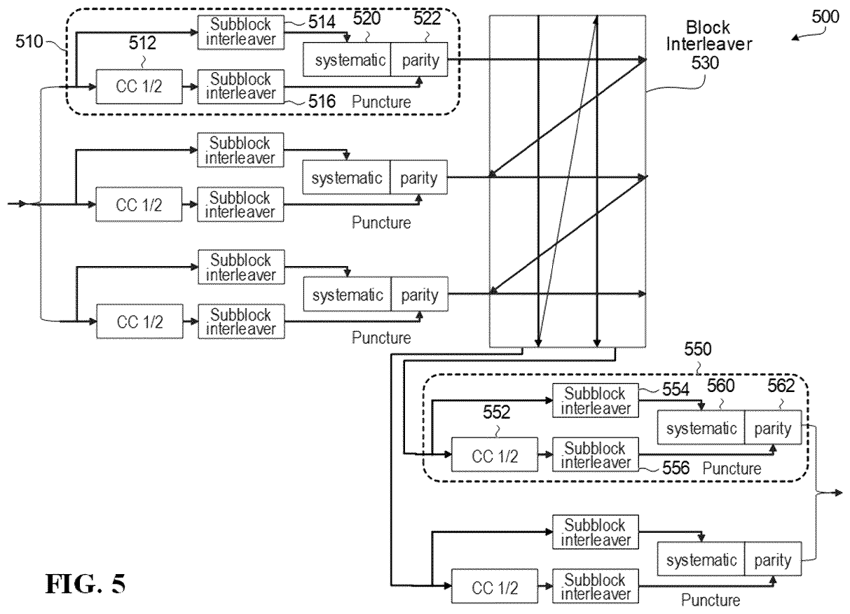

FIG. 5 is a block diagram illustrating an example encoder according to an embodiment. Encoder features or functions may be implemented in any of various ways, such as in hardware, firmware, or one or more components that execute software. The present disclosure is not limited to any specific type of implementation, and implementation details may vary between different devices, for example.

The example encoder 500 includes multiple outer component encoders in respective outer component code modules, one of which is labeled 510, multiple inner component encoders in respective inner component code modules, one of which is labeled 550, and a block interleaver 530, interconnected as shown. The example encoder 500 is representative of an encoder for a woven code with multiple outer codes and inner codes, which may also be referred to as a woven code with a twill.

Each of the component code modules has the same structure in the example shown, and includes a convolutional encoder 512, 552, for a rate 1/2 convolutional code (CC) as an illustrative example, and subblock interleavers 514/516, 554/556. Systematic and parity bits after subblock interleaving are shown at 520, 522 for outer codes and at 560, 562 for inner codes. The systematic bits 520 may also be known as information bits. Bits 520 and 522 together may be known as coded bits or encoded bits. Puncturing is not shown in a separate block in FIG. 5 in order to avoid further congestion in the drawing. The “Puncture” label in FIG. 5 is intended to illustrate that puncturing may be applied to outer code bits and/or to inner code bits for rate matching. In some embodiments, puncturing is applied to parity bits, because puncturing systematic bits or information bits may lead to performance loss. However, in other embodiments, systematic bits or information bits may be mixed or otherwise combined and punctured, by a computer-searched puncturing pattern for example. This may result in some systematic bits or information bits being punctured, but still preserving or at least not significantly impacting performance.

Relative to encoding by a convolutional component encoder only, subblock interleaving and puncturing in the component code modules as shown provide better minimum code distance for component codes.

The example encoder 500 is consistent with an example above, in which systematic bits are routed directly through a subblock interleaver 514, 554, parity bits generated by a convolutional encoder 512, 552 are routed through another subblock interleaver 516, 556, and the two interleaved streams are concatenated and punctured.

The block interleaver 530 implements block interleaving. The horizontal arrows and the diagonal arrows between them at 530 are intended to indicate row-wise writing of respective codewords of the outer codes to memory space, with each written row including one codeword. The vertical arrows and the diagonal arrow between them at 530 are intended to indicate column-wise reading from the memory space for inner coding. Outer code encoded bits that are column-wise read from the memory space are input to the inner component code modules for inner encoding. Inner code encoded bits may also be written to memory space, in column-wise order.

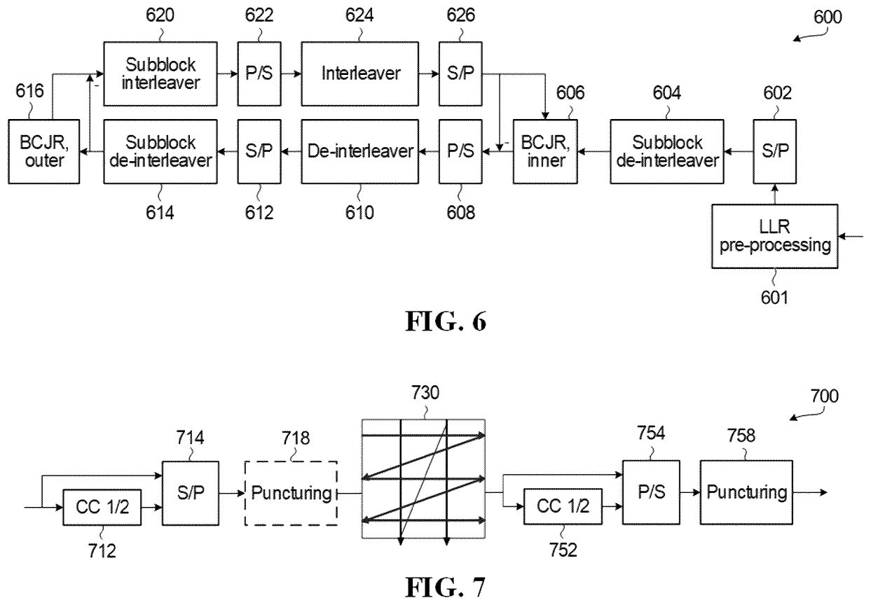

FIG. 6 is a block diagram illustrating an example decoder according to an embodiment. Decoder features or functions may be implemented in any of various ways, such as in hardware, firmware, or one or more components that execute software. The present disclosure is not limited to any specific type of implementation, and implementation details may vary between different devices, for example.

The example decoder 600 includes a log-likelihood ratio (LLR) pre-processing module 601, a serial-to-parallel (S/P) converter 602, a subblock de-interleaver 604, a Bahl-Cocke-Jelinek-Raviv (BCJR) decoder 606 for decoding inner codes, a parallel-to-serial (P/S) converter 608, a block de-interleaver 610, an S/P converter 612, a subblock de-interleaver 614, a BCJR decoder 616 for decoding outer codes, a subblock interleaver 620, a P/S converter 622, a block interleaver 624, and an S/P converter 626, interconnected as shown. The example decoder 600 is representative of a decoder to sequentially decode inner and outer codes at 606, 616, respectively, and iteratively decode a woven code.

In the example shown, the LLR pre-processing module is configured to insert received LLRs, which correspond to confidence levels of transmitted bits, into an LLR buffer with punctured positions being set to LLR=0, or left at LLR=o if the LLR buffer is initialized or preset to zero values. The received, non-punctured LLRs (≠0) and the punctured LLRs (≠O) are jointly de-interleaved at 604 and sent for woven code decoding. Inner and outer component code decoding is generally represented in FIG. 6 at 606, 616, but decoding is iterative in the example shown.

In a simpler coding approach, only one outer code and one inner code are employed, and the subblock interleavers in each component code module are replaced by a simple block interleaver or a P/S converter. FIG. 7 is a block diagram another an example encoder according to such an embodiment.

In the example encoder 700, as in other embodiments, encoder features or functions may be implemented in any of various ways, including the implementation examples provided elsewhere herein. The example encoder 700 includes an outer component encoder 712 and an inner component encoder 752, shown by way of example as rate 1/2 convolutional code encoders. Instead of the subblock interleavers in FIG. 5, the example encoder in FIG. 7 includes a P/S converter 714, 754 respectively coupled to each component encoder 712, 752. Puncturing is shown in FIG. 7 for outer coded bits at 758 and optionally for inner coded bits at 718, and a block interleaver between the outer and inner encoders is shown at 730.

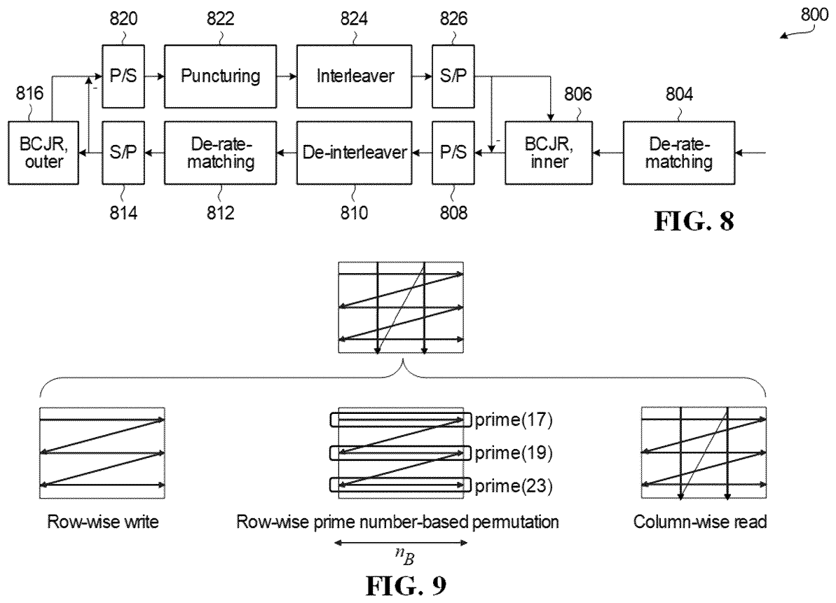

FIG. 8 is a block diagram illustrating an example decoder according to another embodiment, suitable for implementation as a counterpart to the example encoder 700 in FIG. 7. As in other embodiments, decoder features or functions in the example decoder 800 may be implemented in any of various ways, including the implementation examples provided elsewhere herein. The example decoder 800 includes a de-rate matching module 804 to reverse or invert rate matching applied at an encoder or encoding device (such as at 758 in FIG. 7), a BCJR decoder 806 for decoding an inner code, a P/S converter 808, a block de-interleaver 810, an S/P converter 814, a BCJR decoder 816 for decoding an outer code, a P/S converter 820, a block interleaver 824, and an S/P converter 826, interconnected as shown. Optional de-rate matching is shown at 812, and optional puncturing is shown at 822. These optional features are intended to represent reverse or inverse features (for the de-rate matching at 812) or corresponding features (for the puncturing at 822) related to the optional puncturing at 718 in FIG. 7.

The example decoder 800 is another example of a decoder to sequentially decode inner and outer codes at 806, 816, respectively, and iteratively decode a woven code. LLR pre-processing is not separately shown in FIG. 8 in order to avoid further congestion in the drawing, but LLR pre-processing as described at least above with reference to FIG. 6, for example, may be supported or implemented by the de-rate matching module 804.

Block interleaving is an important aspect of woven codes, and some embodiments herein provide a prime number-based row-wise permutation for block interleaving. Possible options to determine or otherwise obtain block interleaving parameters include the following examples for size of a block interleaver: fixed row (width)/column (height) aspect ratio; fixed width; or fixed height.

Row-wise writing and column-wise reading of code bits of an outer code may still be supported, but for each row a respective prime number-based permutation may also be used. The permutations may be based on a list or sequence of prime numbers, such that the permutation for each row is based on a respective different prime number in some embodiments.

As an example, prime number-based permutation may be defined by the following in some embodiments:
Specify a prime number list, for example {3, . . . , 17, 19, 23, 29, 31, . . . }
For the i-th row, i=1,2,3 . . .

Find a next number n in the list, that is coprime with the row length w (width of the block interleaver)—for a prime number list, this is equivalent to skipping w in the list, because a prime number is coprime with any number except itself

$$Calculate {a}_{i} = o : n : ( w - 1 ) n , and {π}_{i} = mod ( {a}_{i} , w ) + 1$$

$$Permute the i - th row according to {π}_{i .}$$

As an example, consider selection of n=3 in the prime number list and w=8, in which case aᵢ={0,3,6,9,12,15,18,21}, and: T={0,3,6,1,4,7,2,5} (indicating bit position indices starting from o) or πi={1,4,7,2,5,8,3,6} (indicating bit position indices starting from 1).

Row-wise writing, with a prime number-based permutation per row and column-wise reading, is shown by way of example in FIG. 9. The example shown in the block diagrams in FIG. 9 includes row-wise writing in the block diagram at the lower left, row-wise prime number-based permutation for each of three rows based on three different prime numbers in the block diagram at the lower middle, and column-wise reading in the block diagram at the lower right.

Rate compatibility is provided in some embodiments with woven-specific recurrent puncturing. In a puncturing pattern, a first value (such as o in a binary puncturing pattern) indicates that a bit in a position corresponding to the first value position in the puncturing pattern is to be punctured and a second value (such as 1 in a binary puncturing pattern) indicates that a bit in a position corresponding to the second value position in the puncturing pattern is to be transmitted. A short “base” puncturing pattern may be used repeatedly until an overall length of the repeated puncturing pattern at least matches mother code length. In this way, a design and search space can be limited to a short binary vector (the base puncturing pattern) rather than the entire code length. This may help make a computer search for a puncturing pattern, for example, much more efficient while achieving close-to-optimal performance. Recurrent puncturing as used herein refers to such repetition or repeated use of the short puncturing pattern, and in this sense puncturing based on a repeated short puncturing pattern may be considered a form of recurrent puncturing.

In an embodiment, recurrent puncturing involves partitioning or segmenting each mother outer code and mother inner code (before row-wise permutation) into segments of a certain length. Segment length may be a small positive integer such as 4, 8,16, 32 . . . , and in some embodiments is coprime with the height of the block interleaver. Each segment is punctured based on a puncturing pattern, with the possible exception of a specified segment such as a last segment. If the last segment (or otherwise specified segment) of an outer/inner mother code has a length that is less than the segment length, then that last segment may be additionally punctured until reaching target code length for rate matching. In some embodiments, dummy bits may be padded at the end of a codeword of a mother code so that padded codeword length is a multiple of segment length, but padded bits need not be transmitted, whether they are punctured or not.

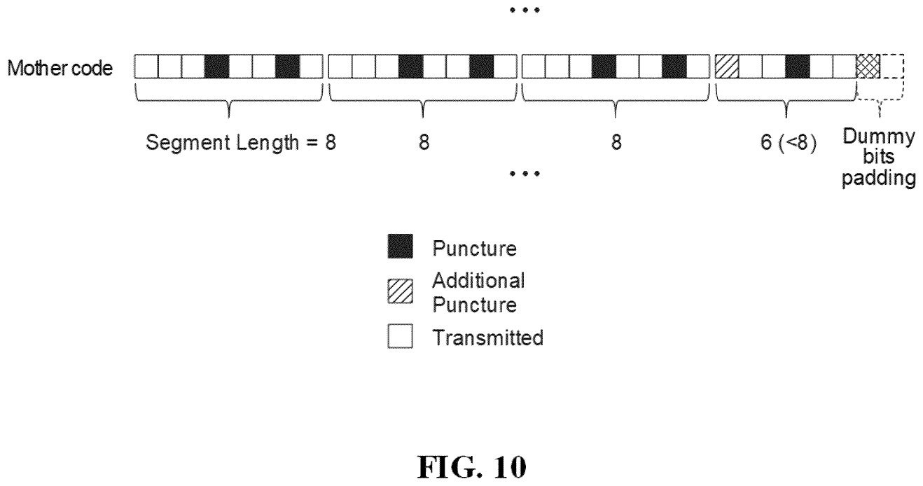

FIG. 10 is a block diagram illustrating an example of puncturing according to an embodiment. In the example shown, segment length is 8, but mother code length is not a multiple of 8; thus, the last segment is a shorter of length 6. A puncturing pattern with o values indicating puncture bit positions to be punctured and 1 values indicating transmit bit positions to be transmitted would be 11101101 in this example. Dummy bits padded at the end of the last segment are shown, and according to the puncturing pattern one of the puncture bit positions is a dummy bit. Therefore, in order to reach target code length an additional bit at another bit position in the last segment is shown as an “Additional Puncture” in FIG. 10.

Turning now to woven encoding in more detail, encoding may be defined or characterized by any of various encoding parameters, such as code length N and information (payload) block length K. For convolutional codes as component codes of a woven code, another encoding parameter is polynomial length. As an example, with polynomial length v=2, the following may be defined for a convolutional code:

$$Forward polynomial : polyf = [ o , 1 ]$$

$$Feedback polynomial : polyb = [ 1 , 1 ]$$

and the same or different polynomials may be used for outer codes and inner codes. For illustrative purposes, the same set of polynomials as shown above is used as an example for outer codes and inner codes. Embodiments are not in any way restricted to codes with the same polynomials.

The size of a block interleaver for block interleaving between outer codes and inner codes may be different for different code lengths and/or different information block length. As also disclosed at least above, possible options to determine or otherwise obtain block interleaving parameters include the following examples for size of a block interleaver: fixed row (width)/column (height) aspect ratio; fixed width; or fixed height. In a fixed width embodiment, width is fixed and height is determined based on one or both of code length and information block length, and therefore changes as one or both of code length and information block length change. In a fixed height embodiment, height is fixed and width is determined based on one or both of code length and information block length, and therefore change as one or both of code length and information block length change. In a fixed aspect ratio embodiment, a ratio between height and width is fixed. Height and width are determined based on one or both of code length and information block length, and both height and width change, to maintain the fixed aspect ratio, as one or both of code length and information block length change.

Of these options, fixed aspect ratio may be preferred for better performance.

Aspect ratio may be denoted by ABr, and in an embodiment is selected from the following values: {5/8, 5/7, 5/6, 4/5, 3/5, 2/5, 3/4}.

In an embodiment, an initial height kA and width kB of an information bit matrix before encoding can be expressed as:

$$kA = ceil ( sqrt ( K + v ) * ABr ) ;$$

$$kB = ceil ( kA / ABr ) .$$

This example is consistent with using a tail-biting convolutional code (TBCC) as for outer coding. In that case, in addition to the K information bits, v tail bits are added before outer encoding. In embodiments that use other convolutional codes or otherwise do not extend the information bits before outer encoding, no v term (or similar term) is used in determining kA.

Encoding may increase bit count, by adding parity bits for example, and in a fixed aspect ratio embodiment both height and width expand to accommodate the increased bit count. After outer encoding, outer code encoded bits are row-wise written in kA rows of width nB=v*kB, and in this example row width is expanded in a kA-by-nB intermediate matrix to accommodate the increased bit count from outer encoding. Block interleaver size further expands to accommodate added bits from inner encoding, to height nA and width nB after inner encoding:

$$nA = v * kA ;$$

$$nB = v * kB .$$

A row-wise permutation for each row of outer code encoded bits in the block interleaver is defined as a permutation matrix of size kA-by-nB to provide an example, and may be denoted as follows, where each row corresponds to a row-wise permutation sequence:

$$BlkPerm = [ \begin{matrix}BlkPerm ( 1 ) \\ ⋮ \\ BlkPerm ( kA )\end{matrix} ] .$$

This permutation matrix has kA rows, and the i-th row, represented by BlkPerm (i), is a permutation sequence for the i-th row in the block interleaver.

For encoding, an encoder encodes an input vector x of length K, and outputs a vector e of length Nm code bits, where Nm is mother code length.

The input vector x may be smaller than the initial block interleaver size kA*kB, in which case zero padding is performed. After padding kA*kB-K zeros at the end, a resultant longer vector xo for encoding is as follows:

$$xo = [ x , o , … , o ] .$$

In addition to the padded information vector xo, another parity-bit vector zo of the length (v-1)*kA*kB is generated by convolutional codes. In the case of v=2, the parity-bit vector zo is of the same length as xo.

Convolutional encoding with trellis termination can be described by the following pseudocode:

```
reg=zeros(1,v);
for i=1:length(xo)
  if i>K
    xo(i)=mod(dot(reg,polyb),2);
  end
  input = mod(dot(reg,polyb)+xo(i),2);
  zo(i) = mod(dot(reg,polyf)+input,2);
  reg(2:end) = reg(1:end−1);
  reg(1) = input;
end
```

The statement xo (i)=mod (dot (reg,polyb),2) relates to trellis termination.

The padded information vector xo and parity-bit vector zo are interleaved into a code vector co:

$$co = [ xo ( 1 ) , zo ( 1 ) , xo ( 2 ) , zo ( 2 ) , … , xo ( kA * kB ) , zo ( kA * kB ) ] .$$

For ease of reference, a kA-by-nB matrix representing a buffer for the block interleaver is denoted BLK. The code vector co is written in row-wise order into BLK, which is of height kA and width nB. Each row of BLK is permuted according to the corresponding row in the permutation matrix BlkPerm. This can be described by the following pseudocode:

```
BLK_perm = zeros(kA,nB);
for i=1:kA
  for j=1:nB
    BLK_perm(i,j) = BLK(i,BlkPerm(i,j));
  end
end
BLK = BLK_perm;
```

The statement BLK_perm (i,j)=BLK (i,BlkPerm (i,j)) relates to permuting each row according to the corresponding permutation sequence for that row.

After permuting the rows in BLK, data is then read from BLK in column-wise order, and padded by v zero bits at the end. The resulting vector of length kA*nB+v may be denoted by xi.

Inner encoding is similar in procedure to outer encoding. In addition to the padded information vector xi, another parity-bit vector zi of the length (v-1)*kA*nB generated by convolutional codes. In the case of v=2, a parity-bit vector zi has the same length as xi.

The convolutional encoding with trellis termination can be described by the following pseudocode:

```
reg=zeros(1,v);
for i=1:length(xi)
  if i> kA*nB
    xi(i)=mod(dot(reg,polyb),2);
  end
  input = mod(dot(reg,polyb)+xi(i),2);
  zi(i) = mod(dot(reg,polyf)+input,2);
  reg(2:end) = reg(1:end−1);
  reg(1) = input;
end
```

The statement xi (i)=mod (dot (reg,polyb),2) relates to trellis termination.

The final codeword vector, denoted by e in this example, is generated by interleaving the padded information vector xi and the parity-bit vector zi:

$$e = [ xi ( 1 ) , zi ( 1 ) , xi ( 2 ) , zi ( 2 ) , … , xi ( kA * nB ) , zi ( kA * nB ) ] .$$

The length of the above mother code is Nm=nA*nB.

For rate matching, the input vector is e, of length Nm code bits, and an output is a punctured code vector c of target length N.

In some embodiments a recurrent binary puncturing pattern is used for puncturing code bits from e. For example, in a length-p puncturing pattern vector punc, a o value may denote a punctured position and a 1 may denote a transmitted position.

For a puncturing input vector e of length Nm and puncturing pattern of length p, the puncturing pattern may be repeated by ceil (Nm/p) times, and then the first Nm bits form a recurrent puncture pattern repunc of length Nm. This can be expressed as follows:

$$repunc = [ punc , … , punc ]$$

$$repunc = repunc ( 1 : Nm )$$

The statement repunc=[punc, . . . , punc] denotes punc being repeated ceil (Nm/p) times, and the statement repunc=repunc (1:Nm) relates to taking the first Nm bits as a recurrent puncturing pattern of length Nm. In some embodiments, one or more additional punctures may be made as shown by way of example in FIG. 10, where a puncture position appears beyond position Nm in repunc=[punc, . . . , punc]. More generally, one or more additional punctures may be made where needed to meet the target length N. This may be expressed as, for example, the number of puncture positions in repunc=repunc (1:Nm) is less than Nm-N, or the number of transmit (non-puncture) positions in repunc=repunc (1:Nm) is greater than N.

Rate matching is achieved by, in effect, extracting the mother code bits corresponding to the first N non-puncture positions in repunc. With o values indicating positions to be punctured and 1 values indicating positions to be transmitted, the first N non-puncture position are the first N non-zero positions in repunc. The following pseudocode represents this type of puncturing:

```
i=1;
c=[ ];
while length(c)<N
  if repunc(i)==1
    c=[c,e(i)];
  end
  i=i+1;
end
```

The punctured code vector c of target length N is obtained, to complete woven encoding.

Row-wise permutation is based on prime numbers in some embodiments. This is described in general above, and a more detailed example follows.

A list or set of prime numbers is configured or otherwise obtained. The following list, plist, is an illustrative and non-limiting example:

plist=[17, 19, 23, 29, 31, 37, 41, 43, 47, 53, 59, 61, 67, 71, 73, 79, 83, 89, 97, 101, 103, 107, 109, 113, 127, 131, 137, 139, 149, 151, 157, 163, 167, 173, 179, 181, 191, 193, 197, 199, 211, 223, 227, 229, 233, 239, 241, 251, 257, 263, 269, 271, 277, 281, 283, 293, 307, 311, 313, 317, 331, 337, 347, 349, 353, 359, 367, 373, 379, 383, 389, 397, 401, 409, 419, 421, 431, 433, 439, 443, 449, 457, 461, 463, 467, 479, 487, 491, 499, 503, 509, 521, 523, 541]

Only prime numbers that have a greatest common divisor (gcd) of 1 with the permutation width nB are used from the list. This is also referenced herein as using numbers from the list that are coprime with row width of a block interleaver. A prime number list generates different permutations between rows, and this type of ged or coprime condition on prime numbers that are to be used for row-wise permutations results in row entries actually being permuted.

A filtered prime number list that does not include any prime number that does not meet this gcd or coprime condition may be denoted by plist1, and can be generated using the following pseudocode, for example:

```
plist1=[ ]
for i=1:length(plist)
  pn=plist(i);
  if gcd(pn,nB)==1
    plist1=[plist1,pn];
  end
end
```

In another embodiment, a filtered prime number list may be generated by searching the prime number list for, and removing from the list, the width nB. The width nB would be the only value in a prime number list that could possibly not be coprime with nB or not have a god of 1 with nB.

The prime number value (also referred to as n in an example above) used for the i-th row in the permutation matrix is plist1 (i).

A permutation sequence is generated by picking an index in every pn=plist1 (i) positions, which provides equal spacing (of pn) between two adjacent index positions, and returning to the beginning in a cyclic manner. With pn being coprime with nB, and equal spacing sampling is used based on pn, all bit positions in a row can be read out in a permuted order. The following provides an example of pseudocode to generate the i-th row of the permutation matrix BlkPerm:

for i=1:kA
BlkPerm(i)= (((0:nB−1)+i−1)*pn)mod(nB)+1;
end

A puncturing pattern is generated a from length-p puncturing pattern vector punc in some embodiments, as referenced above. In practice, the number p is preferably set to be a multiple of v. Numbers from 4, 8, 16, 32 may be preferred in some embodiments, such as where code length is padded to multiples of 8 for example. However, embodiments are not in any way limited to these or any other values.

In order to generate a puncturing pattern vector punc, in some embodiments a permutation sequence ppos of length p is obtained, for example by generating ppos by selecting an index in every pn positions, with equal spacing between two adjacent positions, and returning to the beginning in a cyclic manner, which is similar to a puncturing example provided above. In pseudocode, this may be expressed as follows:

$$ppos = ( ( o : p - 1 ) * pn ) mod ( p ) + 1 ;$$

An average number of bits to be punctured (or, alternatively, transmitted) in every p mother code bits is then determined. Without loss of generality, the first ceil (N/Nm*p) positions in ppos may be positions in punc to be transmitted. In pseudocode, generation of punc may be expressed as follows:

$$punc = zeros ( 1 , p ) ;$$

$$tx\_pos = ppos ( 1 : ceil ( N / Nm * p ) ) ;$$

$$punc ( tx\_pos ) = 1 ;$$

This example illustrates a relationship between permutation and puncturing. For example, if a permutation pattern is [0,2,6,5,7,1,3,4], and the first 5 bits are to be transmitted and the last 3 bits are to be punctured, then the to-be-transmitted bits correspond to bit positions [0,2,6,5,7] in every segment, and the punctured bits correspond to bit positions [1,3,4] in every segment. Equivalently, the puncturing pattern punc in this example is [1,0,1,0,0,1,1,1], and is the same (recurrent) for every segment.

Subblock interleaving and outer code puncturing as disclosed herein are examples of other features that may be provided in some embodiments, and are shown by way of example in FIG. 5.

Subblock interleaving may be provided for either of both of outer component code modules 510 and inner component code modules 550. Subblock interleaving may provide more fine-grained control over minimum distance properties of each individual component code, for example, compared to control over properties of the overall woven code. However, subblock interleaving might not be as description-friendly as block interleaving, and accordingly embodiments with a single block interleaver may be preferred.

Outer code puncturing is shown in the outer component code modules at 510 in FIG. 5, and may enable tuning of outer code rate to the inner code(s). For each overall woven code rate R, there may be an optimal balance between outer code rate R_out and inner code rate R_in, where R in this example may be expressed as R=R_out x R_in.

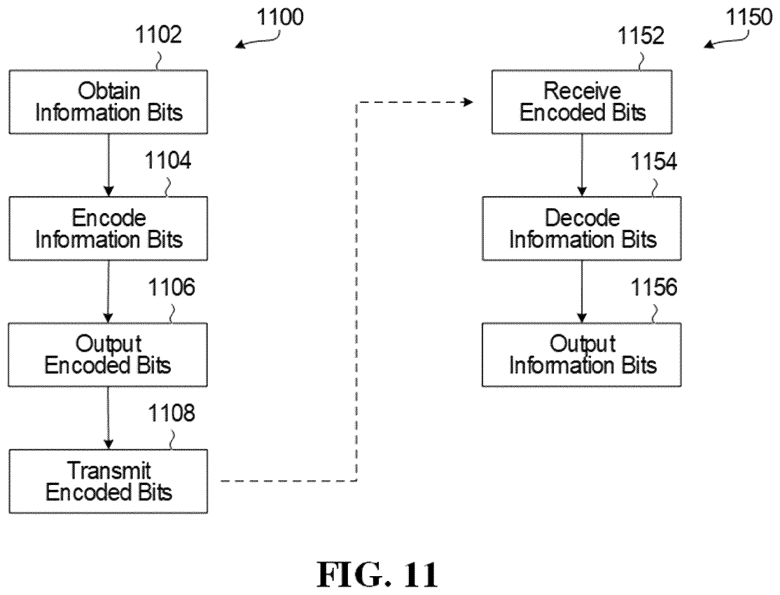

Various aspects of the present disclosure are described above and shown in the drawings by way of example. FIG. 11 is a flow diagram illustrating more general example methods according to embodiments. At the left, 1100 in FIG. 11 illustrates operations or features that may be provided or supported at an encoder or transmitter-side device, and at the right, 1150 illustrates operations or features that may be provided or supported at a decoder or receiver-side device. For ease of reference, in the following description of FIG. 11, a device at which encoding and/or transmitting features may be implemented or supported is called a first communication device, and a device at which decoding and/or receiving features may be implemented or supported is called a second communication device. Embodiments may involve either or both of such devices.

With reference first to 1100, from a transmitting device perspective the transmitting at 1108 is intended to represent transmitting encoded bits by a first communication device to a second communication device in a wireless communication network. The encoded bits are generated by encoding information bits using a woven code, and may be referred to as encoded bits encoded by a woven code. The woven code includes or involves a first code (also referred to herein as an outer code), block interleaving, and a second code (also referred to herein as an inner code). The block interleaving involves row-wise writing of first code encoded bits (that are encoded by the first code) in a number of rows, respective permutations according to which the first code encoded bits in the rows are permuted, and column-wise reading of the permuted first code encoded bits for further encoding by the second code.

FIG. 11 also illustrates operations that may be involved in generating encoded bits. At 1102, FIG. 11 illustrates obtaining information bits, which may involve, for example, collecting or otherwise receiving data outputs from one or more devices and/or services, or accessing data in a memory.

1104 is intended to illustrate encoding of the information bits by the woven code to generate the encoded bits. Although not shown separately in FIG. 11, the encoding at 1104 involves encoding the information bits by the first code, block interleaving first code encoded bits encoded by the first code, and further encoding block interleaved first code encoded bits by a second code. The block interleaving, as described elsewhere herein, involves row-wise writing of the first code encoded bits in rows, permuting the first code encoded bits in the rows according to respective permutations for each row, and column-wise reading of the permuted first code encoded bits for the further encoding by the second code.

As shown at 1106, a method may also involve outputting the encoded bits generated at 1104. The encoded bits may be output for storage to memory, and/or transmission at 1108 for example.

In some embodiments, a method may involve obtaining as shown at 1102, encoding as shown at 1104, and outputting as shown at 1106. Other embodiments may involve transmitting encoded bits as shown at 1108. These embodiments are not mutually exclusive, and methods may involve obtaining and encoding information bits as shown at 1102, 1104, and also transmitting encoded bits as shown at 1106.

As disclosed herein, respective row-wise permutations according to which the rows of first code encoded bits are permuted may be based on respective prime numbers. Embodiments that involve lists of prime numbers and selecting or otherwise obtaining a respective prime number for each row are described herein by way of example.

Rate matching, by puncturing, shortening, or repetition, for example, may also or instead be provided in some embodiments. Rate matching and prime number-based row-wise permutations may be implemented together or separately, and are not dependent upon each other. For example, encoding by a woven code may involve block interleaving in which row-wise permutations are based on respective prime numbers. Rate matching may or may not be applied to encoded bits that have been encoded by the woven code, and/or to encoded bits that are encoded by the first (outer) code. Similarly, rate matching may be applied to encoded bits that are generated by encoding according to a woven code in which block interleaving may or may not involve prime number-based row-wise permutations.

Rate matching may be applied to encoded bits that are encoded by a woven code to rate match the encoded bits to a target code rate. This is shown by way of example in FIG. 5 as “Puncture” in the inner component code modules at 550, and at 758 in FIG. 7. The rate matching may be or include any one or more of: puncturing, shortening, and repetition, and puncturing is shown in the drawings as an example.

In some embodiments, rate matching may involve puncturing based on a puncturing pattern that is shorter than a length of the encoded bits encoded by the woven code. That puncturing pattern, referenced by way of example at least above as “punc”, may be repeated to at least match the length of the encoded bits encoded by the woven code. The extended length of an overall puncturing pattern, also referred to herein as a recurrent puncturing pattern, that results from repeating a shorter puncturing pattern may exceed the length of the encoded bits encoded by the woven code, in which case the puncturing may be based on the puncturing pattern and additional puncturing. For example, where a portion of the repeated puncturing pattern that exceeds the length of the encoded bits encoded by the woven code includes a puncture bit position to be punctured, an additional bit position in the encoded bits may be punctured. An example of this is shown in FIG. 10. Another option is to truncate the repeated puncturing pattern to the mother code length, which is referenced by way of example above as repeating a length p puncturing pattern by ceil (Nm/p) times, and then taking the first Nm bits to form a recurrent puncturing pattern of length Nm.

The size of block interleaving may be based on: a fixed aspect ratio between a row width and a column height, a fixed row width, or a fixed column height. These options are described in further detail elsewhere herein.

A woven code may involve subblock interleaving in component encoding. For example, some embodiments involve subblock interleaving of the first code encoded bits encoded by a first (outer) code, as shown by way of example at 514, 516 in FIG. 5. In such embodiments, row-wise writing for block interleaving involves row-wise writing of subblock interleaved first code encoded bits. Subblock interleaving may also or instead be applied in inner component code encoding, to interleave second code encoded bits encoded by a second (inner) code. This is also shown in FIG. 5, at 554, 556.

Rate matching need not necessarily, or need not only, be applied to encoded bits generated by encoding according to a woven code. For example, rate matching may also or instead be applied to first (outer) code encoded bits. This is shown in FIG. 5 in the outer component code modules at 510, using the example of puncturing. Component code-based rate matching is not limited to puncturing, and may also or instead involve repetition and/or shortening for example. Component code-based rate matching is also not limited only to outer codes.

Embodiments may involve other features or operations that are not explicitly shown in FIG. 11. For example, some embodiments may involve communicating signaling that is indicative of any of various parameters, such as one or more block interleaving parameters, coding parameter related to one or more of outer coding, inner coding, and overall woven coding, etc. Communicating of signaling may involve transmitting the signaling by an encoder/encoding device or a transmitter/transmitting device that is to transmit encoded bits, to a decoder/decoding device or a receiver/receiving device. The communicating may also or instead involve receiving the signaling by a decoder/decoding device or a receiver/receiving device from an encoder/encoding device or a transmitter/transmitting device. Signaling need not necessarily be between, or only between, communication devices by which encoded bits are to be transmitted or received. For example, a network device such as a gNB or a base station may transmit signaling to configure parameters at one or more communication devices. Therefore, a method may involve a network device transmitting signaling, and an encoder/encoding device or a transmitter/transmitting device receiving the signaling from the network device, and/or a decoder/decoding device or a receiver/receiving device receiving the signaling from the network device.

At 1150, FIG. 11 illustrates various decoding and/or receiving counterparts of features shown at 1100. From a receiving device perspective, the receiving at 1152 is intended to represent receiving encoded bits from a first communication device by a second communication device in a wireless communication network. As in other embodiments, the encoded bits are encoded by a woven code, and the woven code includes or involves a first code, block interleaving, and a second code.

FIG. 11 also illustrates operations that may be involved in decoding a codeword. At 1154, FIG. 11 illustrates decoding information bits from encoded bits that are encoded by a woven code, and outputting the information bits, for storage to memory and/or further processing for example, is shown at 1156.

The receiving and decoding at 1152, 1154 may involve different receiving device components or features, but need not be mutually exclusive. Methods may involve receiving encoded bits at 1152 and decoding information bits from the encoded bits at 1154.

As in other embodiments, the information bits have been encoded by the first code to generate the first code encoded bits, the first code encoded bits have been block interleaved by row-wise writing of the first code encoded bits in rows, permuting the first code encoded bits in the rows according to the respective permutations, and column-wise reading of the permuted first code encoded bits, and the column-wise read permuted first code encoded bits have been further encoded by the second code.

Any of various features disclosed herein may be supported or embodied in decoding and/or receiving methods. Examples include the following, any one or more of which may be provided, alone or in any of various combinations:
the respective permutations may be based on respective prime numbers;
a size of the block interleaving may be based on a fixed aspect ratio between a row width and a column height, a fixed row width, or a fixed column height;
the encoded bits may have been rate matched to a target code rate by rate matching applied to the encoded bits at the first communication device-rate matching may be supported or implemented together with or independently from other features such as prime number-based row-wise permutations;
the rate matching may be or include any one or more of: puncturing, shortening, and repetition;
the rate matching may be or include puncturing based on a puncturing pattern that is shorter than a length of the encoded bits encoded by the woven code and is repeated to at least match the length of the encoded bits encoded by the woven code;
the puncturing pattern may be repeated to exceed the length of the encoded bits encoded by the woven code, in which case the puncturing may be based on the puncturing pattern and additional puncturing where a portion of the repeated puncturing pattern that exceeds the length of the encoded bits encoded by the woven code includes a puncture bit position to be punctured;
the woven code may further include or involve subblock interleaving of the first code encoded bits and/or the second code encoded bits;
with subblock interleaving of the first code encoded bits, the row-wise writing for the block interleaving may involve row-wise writing of subblock interleaved first code encoded bits;
rate matching may be applied in component code encoding, to the first code encoded bits and/or the second code encoded bits.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

An apparatus may include a processor and a non-transitory computer readable storage medium, coupled to the processor, storing programming for execution by the processor. In FIG. 3, for example, the processors 210, 260, 276 may each be or include one or more processors, and each memory 208, 258, 278 is an example of a non-transitory computer readable storage medium, in an ED 110 and a TRP 170, 172. A non-transitory computer readable storage medium need not necessarily be provided only in combination with a processor, and may be provided separately in a computer program product, for example.

As an illustrative example, programming stored in or on a non-transitory computer readable storage medium may include instructions to or to cause a processor to transmit, by a first communication device to a second communication device in a wireless communication network, encoded bits encoded by a woven code. Programming stored in or on a non-transitory computer readable storage medium may also or instead include instructions to, or to cause a processor to, encode information bits by a woven code to generate encoded bits and output the encoded bits.

In these and other embodiments, the woven code may include or involve a first code, block interleaving, and a second code, and encoding the information bits to generate encoded bits may then involve encoding the information bits by the first code to generate first code encoded bits, block interleaving the first code encoded bits encoded by the first code, and further encoding block interleaved first code encoded bits by the second code.

The block interleaving involves row-wise writing of first code encoded bits encoded by the first code in a number of rows, respective permutations according to which the first code encoded bits in the rows are permuted, and column-wise reading of the permuted first code encoded bits for further encoding by the second code.

Instructions to encode may be or include instructions to encode the information bits to generate the encoded bits by: encoding the information bits by the first code to generate the first code encoded bits; block interleaving the first code encoded bits by performing the row-wise writing of the first code encoded bits in the plurality of rows, permuting the first code encoded bits in the plurality of rows according to the respective permutations, and performing the column-wise reading of the permuted first code encoded bits; and performing the further encoding by the second code.

Embodiments related to apparatus or non-transitory computer readable storage media may include any one or more of the following features, for example, which are also discussed elsewhere herein:
the respective permutations may be based on respective prime numbers;
a size of the block interleaving may be based on a fixed aspect ratio between a row width and a column height, a fixed row width, or a fixed column height;
rate matching may be applied to the encoded bits encoded by the woven code, to rate match the encoded bits to a target code rate-rate matching may be supported or implemented together with or independently from other features such as prime number-based row-wise permutations;
the rate matching may be or include any one or more of: puncturing, shortening, and repetition;
the rate matching may be or include puncturing based on a puncturing pattern that is shorter than a length of the encoded bits encoded by the woven code and is repeated to at least match the length of the encoded bits encoded by the woven code;
the puncturing pattern may be repeated to exceed the length of the encoded bits encoded by the woven code, in which case the puncturing may be based on the puncturing pattern and additional puncturing where a portion of the repeated puncturing pattern that exceeds the length of the encoded bits encoded by the woven code includes a puncture bit position to be punctured;
the woven code may further include or involve subblock interleaving of the first code encoded bits and/or the second code encoded bits;
with subblock interleaving of the first code encoded bits, the row-wise writing for the block interleaving may involve row-wise writing of subblock interleaved first code encoded bits;
rate matching may be applied in component code encoding, to the first code encoded bits and/or the second code encoded bits.

Programming stored in or on a non-transitory computer readable storage medium may also or instead include instructions to or to cause a processor to receive, from a first communication device by a second communication device in a wireless communication network, encoded bits encoded by a woven code. The woven code may be or include a first code, block interleaving, and a second code, and the block interleaving involves row-wise writing of first code encoded bits encoded by the first code in a number of rows, respective permutations according to which the first code encoded bits in the rows are permuted, and column-wise reading of the permuted first code encoded bits for further encoding by the second code. Such programming may further include instructions to or to cause a processor to decode information bits from the encoded bits. The information bits may have been encoded by the first code to generate the first code encoded bits, the first code encoded bits may have been block interleaved by the row-wise writing of the first code encoded bits in the rows, permuting the first code encoded bits in the plurality of rows according to the respective permutations, and the column-wise reading of the permuted first code encoded bits, and the column-wise read permuted first code encoded bits may have then been further encoded by the second code.

In some embodiments programming includes instructions to or to cause a processor to decode information bits from encoded bits encoded by a woven code that includes or involves a first code, block interleaving, and a second code; and output the information bits. The block interleaving, as in other embodiments, involves row-wise writing of first code encoded bits encoded by the first code in a number of rows, permuting the first code encoded bits in the plurality of rows according to respective permutations for each row of the plurality of rows, and column-wise reading of the permuted first code encoded bits for further encoding by the second code to generate the encoded bits.

Embodiments related to apparatus or non-transitory computer readable storage media may include any one or more of the following features, for example, which are also discussed elsewhere herein:
the respective permutations may be based on respective prime numbers;
a size of the block interleaving may be based on a fixed aspect ratio between a row width and a column height, a fixed row width, or a fixed column height;
the encoded bits may have been rate matched to a target code rate by rate matching applied to the encoded bits at the first communication device-rate matching may be supported or implemented together with or independently from other features such as prime number-based row-wise permutations;
the rate matching may be or include any one or more of: puncturing, shortening, and repetition;
the rate matching may be or include puncturing based on a puncturing pattern that is shorter than a length of the encoded bits encoded by the woven code and is repeated to at least match the length of the encoded bits encoded by the woven code;
the puncturing pattern may be repeated to exceed the length of the encoded bits encoded by the woven code, in which case the puncturing may be based on the puncturing pattern and additional puncturing where a portion of the repeated puncturing pattern that exceeds the length of the encoded bits encoded by the woven code includes a puncture bit position to be punctured;
the woven code may further include or involve subblock interleaving of the first code encoded bits and/or the second code encoded bits;
with subblock interleaving of the first code encoded bits, the row-wise writing for the block interleaving may involve row-wise writing of subblock interleaved first code encoded bits;
rate matching may be applied in component code encoding, to the first code encoded bits and/or the second code encoded bits.

Embodiments disclosed herein encompass various aspects of woven coding.

Rate-compatible component code designs for woven codes are disclosed. Some embodiments may involve subblock interleaving applied after both systematic bits and parity bits, and puncturing after the subblock interleaving, as shown by way of example in FIG. 5. Rate compatibility may help improve performance, and increase flexibility at least because different code rates and code lengths can be achieved.

A row-wise prime number-based permutations are also disclosed, for a main block interleaver between outer codes and inner codes, based on a respective distinct prime number per row, taken from a pre-defined table or list in some embodiments. Row-wise prime number-based permutation may also or instead be referred to as row-wise prime-cyclic-shift permutation in that, in a sense, a cyclic shift is applied to shift each row based on a respective distinct prime number. Potential benefits include better performance and simplicity relative to other types of permutations in woven codes.

Woven code-specific puncturing may involve applying a periodic puncturing pattern to outer component code(s), inner component code(s), or both. Dummy bit padding may be supported and applied if mother code length is not a multiple of puncture pattern length. Such puncturing may also help achieve better performance and simplicity relative to other types of puncturing for rate matching.

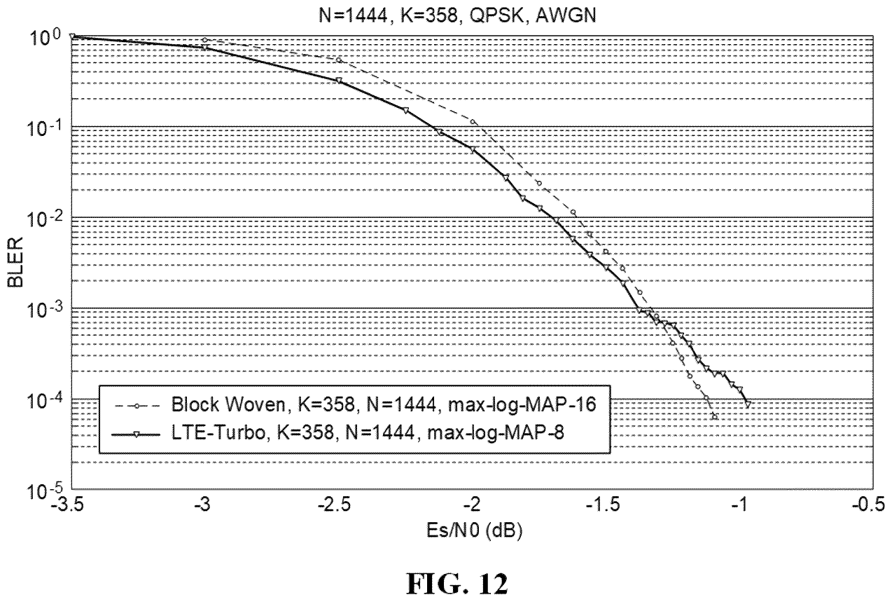

FIG. 12 is a plot of simulation results.

In FIG. 12, “Block Woven” indicates simulation results for a woven code consistent with the present disclosure, and “LTE-Turbo” indicates simulation results for a comparative example.

The other notation in FIG. 12 is as follows:

N=1444 refers to the code length after encoding and rate matching (puncturing); K=358 refers to the information length before encoding; QPSK refers to the modulation scheme, i.e., Quadrature Phase Shift Keying; AWGN refers to channel assumption, i.e., Additive White Gaussian Noise;

max-log-MAP-16 refers to a sub-optimal (but low-complexity) soft decoding algorithm with 16 iterations;

max-log-MAP-8 refers to a sub-optimal (but low-complexity) soft decoding algorithm with 8 iterations.

These are example simulation conditions, and other simulations and/or deployments may be under similar or different conditions and may exhibit similar or different performance.

As shown in FIG. 12, the example woven code outperforms the LTE-Turbo code example at BLER<10⁻³, at code rate 1/4. The woven code curve shows no error floor, while the LTE-Turbo code curve appears to be approaching an error floor. Note that woven codes use simpler component convolutional codes with fewer states, compared with LTE-Turbo codes, and therefore 16 iterations are used for the woven code example instead of 8 iterations for the LTE-Turbo code example to align code complexity.

Although this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

For example, convolutional codes are disclosed as examples. However, embodiments are not limited to convolutional codes.

The disclosed embodiments also refer to component codes and in particular outer and inner codes of a woven code. Such codes that are applied sequentially or serially in woven coding, before and after block interleaving, may be referred to differently. For example, component codes are also generally referenced herein as first and second codes.

Features disclosed herein in the context of method embodiments, for example, may also or instead be implemented in apparatus or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Although aspects of the present invention have been described with reference to specific features and embodiments thereof, various modifications and combinations can be made thereto without departing from the invention. The description and drawings are, accordingly, to be regarded simply as an illustration of some embodiments of the invention as defined by the appended claims, and are contemplated to cover any and all modifications, variations, combinations or equivalents that fall within the scope of the present invention. Therefore, although embodiments and potential advantages have been described in detail, various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and nonremovable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

What is claimed is:

1. A method comprising:
transmitting, by a first communication device to a second communication device in a wireless communication network, encoded bits encoded by a woven code, the woven code comprising a first code, block interleaving, and a second code,
the block interleaving comprising row-wise writing of first code encoded bits encoded by the first code in a plurality of rows, respective permutations according to which the first code encoded bits in the plurality of rows are permuted, and column-wise reading of the permuted first code encoded bits for further encoding by the second code, and
the respective permutations being based on respective prime numbers.

2. The method of claim 1, further comprising encoding information bits by the woven code to generate the encoded bits, the encoding comprising:
encoding the information bits by the first code to generate the first code encoded bits;
block interleaving the first code encoded bits by performing the row-wise writing of the first code encoded bits in the plurality of rows, permuting the first code encoded bits in the plurality of rows according to the respective permutations, and performing the column-wise reading of the permuted first code encoded bits; and
performing the further encoding by the second code.

3. The method of claim 1, wherein a size of the block interleaving is based on a fixed aspect ratio between a row width and a column height, a fixed row width, or a fixed column height.

4. The method of claim 1, wherein rate matching is applied to the encoded bits encoded by the woven code, to rate match the encoded bits to a target code rate.

5. The method of claim 4, wherein the rate matching comprises any one or more of: puncturing, shortening, or repetition.

6. The method of claim 4, wherein the rate matching comprises puncturing based on a puncturing pattern that is shorter than a length of the encoded bits encoded by the woven code and is repeated to at least match the length of the encoded bits encoded by the woven code.

7. The method of claim 6, wherein the puncturing pattern is repeated to exceed the length of the encoded bits encoded by the woven code, and the puncturing is based on the puncturing pattern and additional puncturing where a portion of the repeated puncturing pattern that exceeds the length of the encoded bits encoded by the woven code includes a puncture bit position to be punctured.

8. The method of claim 1, wherein the woven code further comprises subblock interleaving of the first code encoded bits, wherein the row-wise writing comprises row-wise writing of subblock interleaved first code encoded bits.

9. The method of claim 1, wherein rate matching is applied to the first code encoded bits.

10. An apparatus comprising:
at least one processor; and
at least one non-transitory computer readable storage medium, coupled to the at least one processor, storing programming for execution by the at least one processor, the programming including instructions to:
transmit, to a second communication device in a wireless communication network, encoded bits encoded by a woven code, the woven code comprising a first code, block interleaving, and a second code,
the block interleaving comprising row-wise writing of first code encoded bits encoded by the first code in a plurality of rows, respective permutations according to which the first code encoded bits in the plurality of rows are permuted, and column-wise reading of the permuted first code encoded bits for further encoding by the second code, and
the respective permutations being based on respective prime numbers.

11. The apparatus of claim 10, the programming further including instructions to encode information bits to generate the encoded bits by:
encoding the information bits by the first code to generate the first code encoded bits;
block interleaving the first code encoded bits by performing the row-wise writing of the first code encoded bits in the plurality of rows, permuting the first code encoded bits in the plurality of rows according to the respective permutations, and performing the column-wise reading of the permuted first code encoded bits; and
performing the further encoding by the second code.

12. The apparatus of claim 10, wherein a size of the block interleaving is based on a fixed aspect ratio between a row width and a column height, a fixed row width, or a fixed column height.

13. The apparatus of claim 10, wherein rate matching is applied to the encoded bits encoded by the woven code, to rate match the encoded bits to a target code rate.

14. The apparatus of claim 13, wherein the rate matching comprises any one or more of: puncturing, shortening, or repetition.

15. The apparatus of claim 13, wherein the rate matching comprises puncturing based on a puncturing pattern that is shorter than a length of the encoded bits encoded by the woven code and is repeated to at least match the length of the encoded bits encoded by the woven code.

16. The apparatus of claim 15, wherein the puncturing pattern is repeated to exceed the length of the encoded bits encoded by the woven code, and the puncturing is based on the puncturing pattern and additional puncturing where a portion of the repeated puncturing pattern that exceeds the length of the encoded bits encoded by the woven code includes a puncture bit position to be punctured.

17. The apparatus of claim 10, wherein the woven code further comprises subblock interleaving of the first code encoded bits, wherein the row-wise writing comprises row-wise writing of subblock interleaved first code encoded bits.

18. The apparatus of claim 10, wherein rate matching is applied to the first code encoded bits.

19. A method comprising:
receiving, from a first communication device by a second communication device in a wireless communication network, encoded bits encoded by a woven code, the woven code comprising a first code, block interleaving, and a second code,
the block interleaving comprising row-wise writing of first code encoded bits encoded by the first code in a plurality of rows, respective permutations according to which the first code encoded bits in the plurality of rows are permuted, and column-wise reading of the permuted first code encoded bits for further encoding by the second code, and
the respective permutations being based on respective prime numbers.

20. The method of claim 19, further comprising decoding information bits from the encoded bits,
the information bits having been encoded by the first code to generate the first code encoded bits;
the first code encoded bits having been block interleaved by the row-wise writing of the first code encoded bits in the plurality of rows, permuting the first code encoded bits in the plurality of rows according to the respective permutations, and the column-wise reading of the permuted first code encoded bits; and
the column-wise read permuted first code encoded bits having been further encoded by the second code.
